(19) United States
(12) Patent Application Publication
(10) Pub. No.: US 2005/0007108 A1
(43) Pub. Date: Jan. 13, 2005

(54) Probes and methods for detecting defects in metallic structures

(76) Inventor: Teodor Dogaru, Charlotte, NC (US)

Correspondence Address: John C. Alemanni, Esq.;Kilpatrick Stockton LLP, 1001 West Fourth Street, Winston-Salem, NC, 27101-2400, US

(21) Appl. No.: 10/617,948

(22) Filed: Jul. 11, 2003

(51) Int. Cl. G01N 27/72; G01R 33/12; G01N 27/82

(52) U.S. Cl. 324/235; 324/750; 324/239

(57) ABSTRACT

The present invention is directed to configurations of eddy current probes and methods for using these probes to detect cracks initiating at the edge of holes in single-layered or multi-layered metallic structures. The new devices and methods are suitable to detect buried cracks around fastener holes located in layers of multi-layered structures, for example in airplane wing splices, containing fasteners disposed in rows. The probes include excitations coils and one or more magnetic sensors. The magnetic sensors can be arranged in absolute, differential or array configurations. The probe is scanned linearly along the fastener row. The invention also contains an apparatus or system for monitoring cracks around holes, including signal processing circuits, driving circuits, data acquisition and display, and scanning systems.

### FIELD OF THE INVENTION

The present invention relates to the nondestructive evaluation (NDE) of metallic structures.

### BACKGROUND

There is an increased interest in the nondestructive evaluation (NDE) community in detecting fatigue cracks within assembled structures and, in particular, around fastener holes in aging aircraft. The detection of deep and small cracks initiating within the bore of multi-layered structures without removing the fastener represents a considerable problem, In particular, second and third layer flaw detection is a challenge for any of the NDE inspection methods currently in use.

Conventionally, the detection of deeply buried flaws is carried out by using either eddy current testing techniques or ultrasound methods. The drawback of ultrasound methods is that they are not effective in detecting lower-layer flaws. In contrast, within eddy current techniques, the electromagnetic field is not perturbed by the presence of the interfaces between layers.

An important application of the eddy current probes is the detection of cracks around fastener holes in multi-layer metal structures. A typical example is the wing splice structure in airplanes. These structures are held together by rows of steel taper-lock fasteners. Cracks can occur around the fasteners holes in each of the structure layers. It is important to detect these cracks at the initial stage of development.

Depending on the direction of stresses during the flight, typically, there are two types of cracks around fastener holes, longitudinal cracks that initiate and propagate along a fastener row and transversal cracks that propagate perpendicular to the fastener row. Longitudinal cracks are the most critical, because they can propagate from a fastener hole to the adjacent hole (‘zipping’ effect), potentially causing major structural failure. Transversal cracks can propagate across the structure towards its edge, especially in relatively narrow structures.

Advances in magnetic sensor technology make electromagnetic nondestructive evaluation methods attractive for addressing the problem of crack detection. To detect deep or buried flaws, a low frequency electromagnetic field is induced in the specimen under test (SUT). Traditionally, eddy current testing methods using excitation-detection coils are fundamentally limited by the poor sensitivity of the detection coils at low frequencies.

Eddy current testing for detecting deep cracks is currently carried out by using probes that contain both excitation and detection elements scanned on one side of a metallic structure. To test thick structures, low frequency eddy current must be induced in the specimen by excitation coils of relatively large diameter. Due to their high sensitivity to low frequencies, magnetoresistive sensors tend to replace inductive coils as detecting elements in these applications.

The use of magnetoresistive sensors has several advantages over inductive coils. These advantages include the capability of detecting deeply buried flaws as well as surface cracks because of the high sensitivity from a DC to megahertz domain and low noise. In addition, high-spatial resolution flaw detection is possible because of small dimensions, on the order of tens of micrometers. Being fabricated using planar technology, thin film magnetoresistive sensors can be manufactured in customized arrays. Suitably patterned arrays are very attractive for mapping the magnetic field without the need of scanning the area of interest. Magnetoresistive sensors also have a relatively low associated cost, making them attractive for commercial eddy current probes.

A self-nulling giant magnetoresistive (GMR)-based eddy current probe has been proposed that contains a cylindrical excitation coil and a GMR sensor placed on the symmetry axis of the coil. The GMR sensor detects the component of the magnetic field along the axis of the coil. A flux-focusing lens enhances the depth of penetration of the field into the specimen under test and, at the same time, reduces the influence of the excitation field on the sensor's output. To totally cancel the influence of background fields at the GMR sensor location, an active feedback is used. A small buckle coil placed near the sensor but far enough from the specimen under test, such that it does not influence the eddy currents within the specimen, creates this compensation field. Relatively long cracks grown on either side of a hole and electro-discharge machined (EDM) notches were successfully detected in multi-layers of aluminum plates. Best results show that a 14 mm long, 0.12 mm wide notch machined through a 1 mm thick aluminum plate has been detected under a 9 mm thick stack of aluminum plates.

Another approach for the inspection of deep cracks around fastener holes uses a cylindrical air-cored excitation coil placed above the taper fastener, concentric to the hole. The diameter of the excitation coil is larger than the diameter of the hole. An anisotropic magnetoresistive (AMR) sensor is positioned interior to the coil, above the periphery of the hole, where cracks can initiate. The sensitive axis of the AMR sensor is oriented tangential to the specimen surface and radially with respect to the center of the hole. Another identical sensor is placed symmetrical on the opposite side of the hole to compensate for the hole edge signal. Pulsed eddy currents are used for inducing the excitation field into the specimen. The technique has the advantage of creating a higher intensity excitation field than that achievable using single frequency excitation. A notch of 3 mm in length and 4 mm in height was detected at 20 mm depth under the surface, while a notch of 1 mm in length and 1 mm in height was detected at 5 mm below the surface.

Another approach uses a probe geometry based on a coil, which induces a uniform field in the area under inspection. A coil containing a sheet of flat parallel strips of copper deposited on a fiberglass substrate creates a uniform magnetic field oriented coplanar with the specimen surface and perpendicular to the coil's current direction. A very sensitive AMR sensor placed in the center of the coil detects the magnetic field in a direction perpendicular to the specimen surface. Because of the geometry of the excitation coil, the probe is insensitive to lift-off variations during scanning. To separate the flaw signal from other background signals, such as those due to the fastener or edges, additional compensation techniques are used. Slots of 6.3 mm length, 6.3 mm height, 0.2 mm wide in the lowest layer of a stack of three aluminum plates totaling 25 mm in thickness are detectable in the presence of stainless steel fasteners.

Probes have been proposed that take advantage of the symmetry of the specimen to eliminate the edge and fastener signals. Shaped excitation coils properly positioned with respect to the hole are used to focus all eddy currents paths at the edge of the hole. Consequently, the perturbation of the eddy current flow due to the presence of a crack initiating at the edge is greatly enhanced. By placing a spin dependent tunneling (SDT) sensor close to the specimen surface, above the hole's edge, and using a proper orientation of the SDT sensitive axis, the signal from the crack is detected, while the signal from the edge does not influence the sensor's output. The probe is rotated around the hole to test the circumference of the hole. Using this method, a small corner crack of 2.8 mm length, 2.8 mm height and 0.15 mm width, initiating from the edge of a 19 mm diameter can be detected at the bottom of a 13 mm two-layer aluminum structure.

Methods for the early detection of buried cracks are desired that are simple to use and that reduce the scanning time and the associated costs.

### SUMMARY OF THE INVENTION

The present invention relates to the nondestructive evaluation (NDE) of metallic structures using electromagnetic testing (ET) via eddy currents. An excitation coil creates eddy currents in the specimen to be tested, and the perturbation of the magnetic field due to a crack is detected by using a solid-state magnetic sensor, for example a giant magnetoresistance (GMR) or spin-dependent tunneling (SDT) sensor.

For cracks around small diameter holes, linear scanning methods are preferable to circular scanning methods. A method according to the present invention single line scans a surface rather than raster-scanning the surface, significantly reducing inspection time. This method is based on symmetry considerations. Single scanning lines are selected such that the eddy current loops induced in the tested material are symmetric about the scanning line. In this way, in the absence of cracks and by using a proper orientation of the sensitive axis of the magnetic sensor (GMR or SDT), the output of the sensor is theoretically zero. A crack or other detectable flaw will break the symmetry of the loops about the scanning line, creating a signal at the sensor.

To obtain the desired symmetry, the scanning line is positioned to coincide with the diameter of the hole to be inspected and is directed perpendicular to the direction of the cracks. For transverse cracks, the scanning line is directed along or parallel to the symmetry axis of the fastener row. Any transverse cracks will break the symmetry about this axis. For longitudinal cracks, the scanning line is directed perpendicular to the fastener row. The detection of cracks in various layers or at different depths is performed by using multi-frequency excitation or by using single frequency excitation and phase discrimination of the crack signal.

In one embodiment of the invention, the eddy current probe consists of a flat rectangular excitation coil that has a long dimension and a magnetoresistive sensor located on the coil's axis of symmetry, with the axis of sensitivity of the sensor coplanar with the flat coil and perpendicular to the long dimension of the flat coil. This probe is suitable for detecting transverse cracks in a row of fastener holes when the probe is scanned along the row axis.

In another embodiment of the invention, the eddy current probe consists of a flat rectangular excitation coil and a linear array of magnetoresistive sensors located on the coil's axis of symmetry. This probe is suitable for mapping near surface defects such as cracks and corrosion, requiring only a linear scan to obtain the image of a two-dimensional area.

### BRIEF DESCRIPTION OF THE DRAWINGS

FIG. 1 is schematic representation of a multi-layer specimen for testing;

FIG. 2 is a schematic representation of the principle of operation of an eddy current probe configuration in accordance with the present invention;

FIG. 3 is a schematic representation of a method for detecting transverse cracks in fastener holes by using a linearly scanned circular eddy current probe;

FIG. 4 is a schematic representation of a method for detecting longitudinal cracks around fastener holes by using a linearly scanned circular eddy current probe;

FIG. 5 is a schematic representation of an eddy current probe based on a flat rectangular excitation coil and a magnetic sensor in accordance with the present invention;

FIG. 6 is a schematic representation of an eddy current probe based on a rectangular, double-spiral excitation coil and a magnetic sensor in accordance with the present invention;

FIG. 7 is a schematic representation of two crossed rectangular excitation coils and a magnetic sensor in accordance with the present invention;

FIG. 8 is a schematic representation of a flat rectangular coil and two-sensor configuration in accordance with the present invention;

FIG. 9 is a schematic representation of a rectangular, double-spiral coil and two-sensor configuration in accordance with the present invention;

FIG. 10 is a schematic representation of a rectangular double-spiral coil and linear sensor array configuration in accordance with the present invention;

FIG. 11 is a schematic representation of a flat rectangular excitation coil and a linear array of sensors in accordance with the present invention;

FIG. 12 is a schematic representation of a remote field eddy current probe embodiment in accordance with the present invention;

FIG. 13 is a schematic representation of a reflection—remote field eddy current probe embodiment in accordance with the present invention;

FIG. 14 is a plan view of two specimens for testing with eddy current probes in accordance with the present invention;

FIG. 15 is a plan view of a flat rectangular coil manufactured from a ribbon cable in accordance with the present invention;

FIG. 16 is a perspective view of a reflection eddy current probe embodiment in accordance with the present invention;

FIG. 17 is a graphical representation of the results from scanning a specimen using an eddy current probe embodiment containing a rectangular spiral excitation coil in accordance with the present invention;

FIG. 18 is a graphical representation of the results from scanning another specimen using an eddy current probe embodiment containing a rectangular spiral excitation coil in accordance with the present invention;

FIG. 19 is a graphical representation of the results from scanning yet another specimen using an eddy current probe embodiment containing a rectangular spiral excitation coil in accordance with the present invention;

FIG. 20 is a graphical representation of the results from scanning a specimen using an eddy current probe embodiment containing a double spiral excitation coil in accordance with the present invention;

FIG. 21 is a graphical representation of the results from scanning another specimen using an eddy current probe embodiment containing a double spiral excitation coil in accordance with the present invention;

FIG. 22 is a graphical representation of the results from scanning a specimen using a remote field eddy current probe embodiment in accordance with the present invention;

FIG. 23 is a graphical representation of the results from scanning a specimen using a reflection-remote field eddy current probe embodiment in accordance with the present invention;

### DETAILED DESCRIPTION

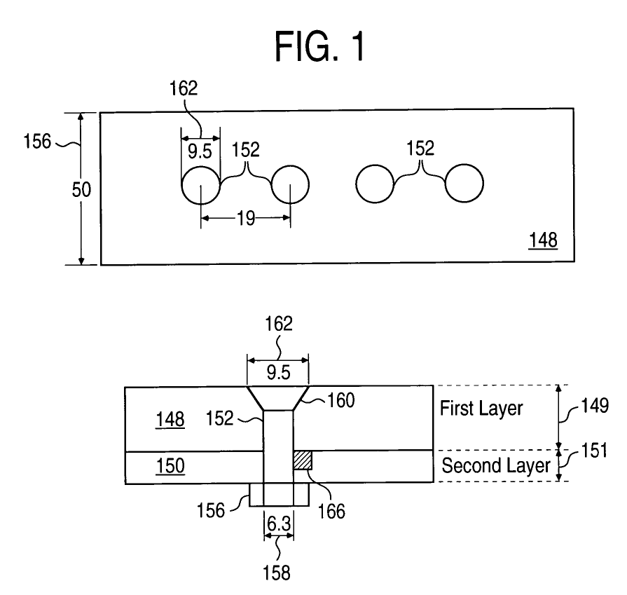

A typical structure comprising a row of fastener for which one embodiment of the present invention may be used to detect cracks is shown in FIG. 1. The specimen contains two layers, a plurality of fastener holes disposed in a row and cracks in the second layer emanating from the fastener holes. As illustrated in FIG. 1, both the first layer 148 and the second layer 150 were constructed from a rectangular aluminum plate containing a row of fastener holes. The holes 152 in each plate were aligned, and the two plates were held joined together using a plurality of taper-lock fasteners 154. A single taper-lock fastener 154 was passed through each hole 152 and secured in place by fastener nut 156 attached to the distal end of each fastener 154. Each hole 152 also included a tapered section 160 in the first layer 148 to provide for countersinking of the taper-lock fastener 154. The specimen was covered with a thin layer of protective paint. The specimen also included cracks 166 disposed in the second layer 150 and emanating from selected holes.

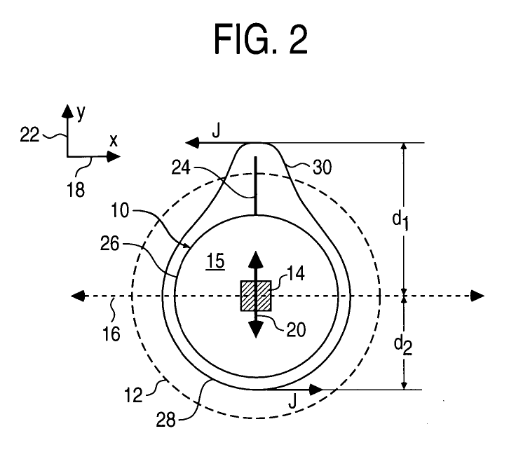

The principle of operation of one eddy current probe according to the present invention is shown schematically in FIG. 2. The top view of a fastener hole 10 containing a radial crack emanating from its edge is shown in FIG. 2. Also illustrated are a circular excitation coil 12 and a centered giant magnetoresistive (GMR) sensor 14 that constitute the eddy current probe. The GMR sensor 14 has an axis of sensitivity 20 along the y-direction (FIG. 2). The eddy current probe is scanned above the top surface of the specimens, over the fastener hole so that it follows a scanning line 16 that runs along the diameter of the fastener hole 10. The scanning line 16 is arranged in a direction, for example x-axis 18, that is perpendicular to the axis of sensitivity 20 of the GMR sensor, that coincides with the y-axis 22.

A fastener hole 10 that is free from any cracks or defects, due to the circular symmetry, will yield a magnetic field perpendicular to the scanning line 16 that is zero at any point along the scanning line 16. A fastener hole 10 containing a crack 24 propagating radially out from the hole edge 26 in a direction perpendicular to the scanning line 16, as illustrated in FIG. 2, will produce a non-zero magnetic field in the direction perpendicular to the scanning line 16. The crack can be disposed in the first layer, the second layer, or both the first and second layers.

The crack 24 will cause the eddy current loop 28 to deflect or deviate in the area 30 around the crack 24. This deviation will result in an eddy current loop 28 that is asymmetric about the scanning line 16. Therefore, the eddy current loop 28 will extend a first distance d₁ on the side of the scanning line 16 containing the crack that is greater than a second distance d₂ that the eddy current loop extends on the opposite side of the scanning line 16, resulting in a non-zero component of the magnetic field in the direction perpendicular to the scanning line, for example the y-direction. The GMR sensor 14 detects the non-zero component of the magnetic field. In the example illustrated in FIG. 2, the peak non-zero component of the magnetic field detected by the GMR sensor 14 occurs when the GMR sensor 14 passes over the center of the fastener hole 10, because the asymmetry of the eddy current loop 28 is maximized at that point.

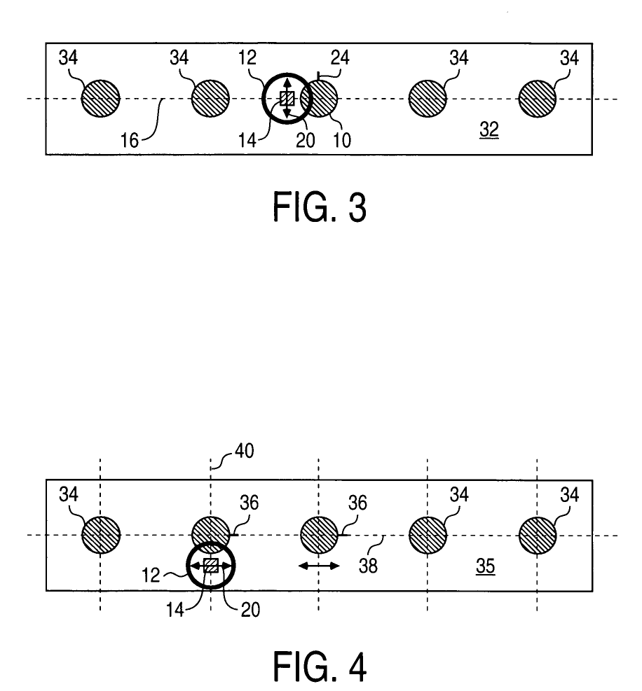

FIG. 3 illustrates the fastener hole 10 located in a specimen 32 to be tested and disposed in a row with a plurality of additional holes 34. As illustrated the crack 24 is arranged transverse or perpendicular to the symmetry axis 16 of the specimen 32, which runs through both the fastener hole 10 containing the crack and each one of the plurality of additional holes 34. The scanning line 16 coincides with the symmetry axis of the specimen 32, and the GMR sensor's axis of sensitivity 14 is oriented in the direction of the crack 24. This arrangement is suitable for detecting transverse cracks in a row of fastener holes. An eddy current probe comprising a circular excitation coil 12 and a GMR sensor disposed at the center of symmetry of the coil is scanned along the row of fastener holes.

The detection of longitudinal cracks is shown in FIG. 4. As illustrated, the longitudinal cracks 36 in a specimen 35 run generally in the direction of the axis 38 of the plurality of holes 34 in a row. The axis of sensitivity 20 is oriented perpendicular to the scanning axis 40 running along a diameter of each hole and aligned to achieve the desired symmetry in the magnetic field. Therefore, the scanning axis 40 is perpendicular to the axis 38 of the holes, necessitating a plurality of successive scans along successive parallel scanning lines 40 that each coincide with the transverse diameter of holes. The distance between two successive scanning lines 40 is generally equal to the distance between the centers of two adjacent holes 34.

Alternatively, the scanning lines 40 can be disposed at the mid-distance between two adjacent holes 34 (not shown). Since, in general, the distance between adjacent holes 34 is greater than the diameter of each hole, larger excitation coils 12 are used to provide eddy currents that intercept the cracks 36. Larger excitation coils 12 also provide the advantage of permitting cracks that are disposed at greater depths within the specimen to be detected.

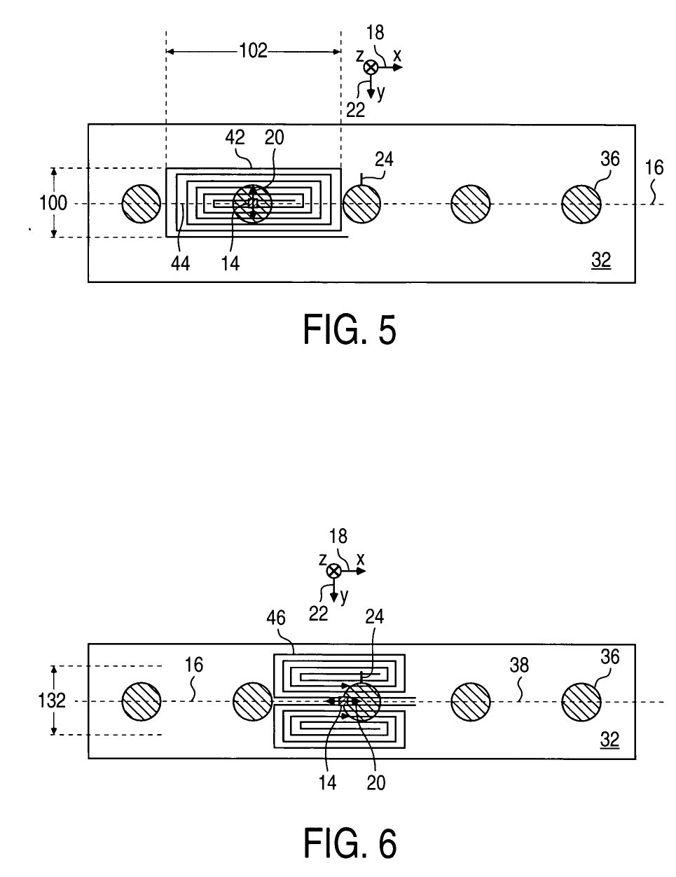

Various arrangements of the sensor and excitation coil that constitute the eddy current probe in accordance with the present invention are possible. For example as illustrated in FIGS. 3 and 4, the GMR sensor 14 can be disposed on the center of a circular excitation coil 12. The manufacturing of a suitably symmetric coil is difficult, and the alignment within the probe and during scanning above the specimen surface is difficult to achieve. In another embodiment as shown for example in FIG. 5, a rectangular excitation coil 42 can be used. A rectangular excitation coil has a rectangular cross section. The rectangular excitation coil 42 can be constructed from a ribbon cable having parallel, insulated wires. The rectangular excitation coil can be applied and used just like a circular excitation coil. Multiple rectangular excitation coils may be used in concert. For example, in one embodiment, the excitation coil includes a pair of identical rectangular coils symmetrically disposed about the symmetry axis of the two coils.

The rectangular excitation coil 42 provides the advantage that the necessary coil symmetry can be achieved by properly connecting the wires at the end of the ribbon cable. The GMR sensor 14 is placed on the longitudinal axis 44 of the coil so that the axis of sensitivity 20 is perpendicular to the wires in the ribbon cable and the current lines. In order to scan the specimen 32, the eddy current probe is passed across the specimen 32 such that the longitudinal axis 40 of the rectangular excitation coil 42 is aligned with the scanning line 16 to produce a zero output in the probe due to the symmetry of the magnetic field. A crack 24 emanating from a hole breaks the symmetry of the field, producing a non-zero output in the probe.

The use of ribbon cable for the rectangular excitation coil provides advantages over other flat linear coils such as those that are produced on printed circuit boards (PCB). For example, the use of ribbon cable for linear coils permits the use of higher currents in the wires of the ribbon cable, which induce a higher density of eddy currents in the specimen. Since the ribbon cable is flexible, it can conform to a variety of surface shapes, for example cylindrical or spherical surfaces, and is not limited to use with flat surfaces, as are excitations coils disposed on a PCB. In addition, flexibility allows the ends of the ribbon cable to be easily bent to adjust the length of the coil to fit specific applications.

The use of ribbon cable for the coil permits greater flexibility in coil configuration. For example, a pair of standard electrical connectors can be attached to either end of the ribbon cable. Different coil configurations can then be achieved by using various arrangements of jumper wires connected at selected locations across the ribbon. Therefore different coil configurations can be designed on the same cable simply by changing the jumper connectors. Another advantage of ribbon cable results from the plastic insulation in which the cable is packaged. The plastic insulation allows the cable to slide along the surface of the specimen to be inspected without damaging the surface of the specimen, for example without defacing the specimen or scratching the paint. This permits the use of handheld eddy current probes that can be scanned in mechanical contact with the specimen surface. The ability to have mechanical contact between the probe and the specimen minimizes probe lift-off and allows probe lift-off to be maintained at a constant value.

The excitation coil may be multi-layer. For example, in another embodiment as illustrated in FIG. 6, the excitation coil can be arranged as a flat, linear, double spiral coil 46. In this embodiment, the GMR sensor 14 is disposed above the center of the coil. The double spiral coil 46 and sensor 14 are passed along the axis of the row of holes 36 to detect transverse cracks emanating radially from each hole. The axis of sensitivity 20 of the double spiral coil 46 runs between the coils and during a scan is oriented along the axis of the row of holes 38. The double spiral coil 46 also produces a self-nulling probe, and in the absence of cracks, the holes 36 symmetrically split the eddy current flow around their edges, producing a zero output in the probe.

When a crack 24 is encountered in one of the holes 36, the splitting of the eddy current around the edge of that hole will be asymmetrical in a direction transverse to the axis of sensitivity, for example in the direction of the y-axis 22. This asymmetry of the eddy current density along the y-axis 22 produces a magnetic field in the direction of the axis of sensitivity that is in the direction of the x-axis 18. The GMR sensor 14 detects this magnetic field along the x-axis 18. In general, the double spiral coil 46 has a larger area than the circular or rectangular coils. This larger area permits the detection of cracks located deeper within the specimen 32.

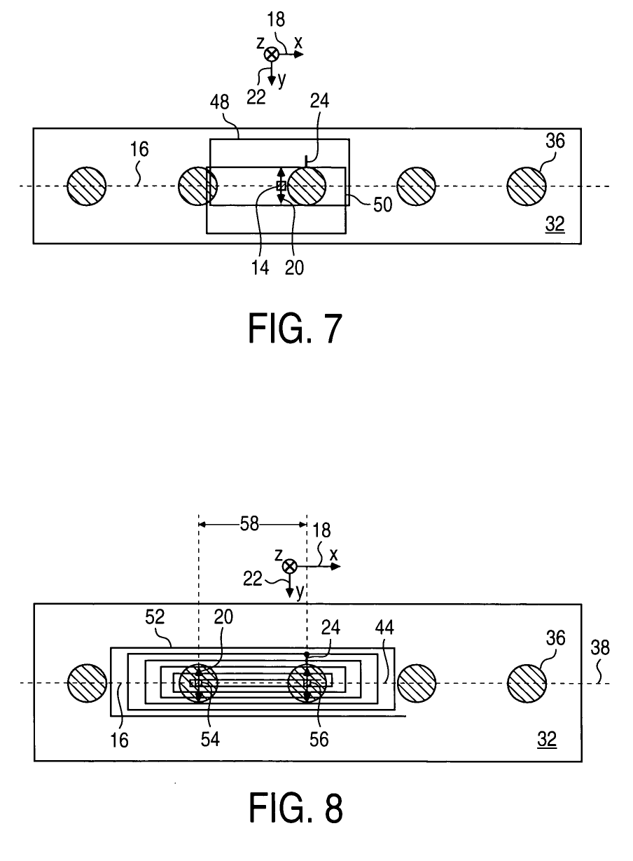

Alternatively, as illustrated in FIG. 7, the double spiral coil 46 embodiment can be arranged as an intersecting double spiral coil 48. In this embodiment, the two spirals intersect or cross each other in a central region 50. Although the spirals can be made to cross or intersect through positioning, preferably, each coil is made larger so that the two coils overlap. Therefore, each one of the coils will occupy a larger area than the coils illustrated in FIG. 6. In this embodiment, the axis of sensitivity 20 is transverse to the scanning line 16.

Alternative embodiments of eddy current probes in accordance with the present invention utilize a plurality of sensors. The use of two or more sensors arranged in a differential or adder configuration improves the detection capability of the eddy current probes. The advantages of multi-sensor arrangements over single-sensor arrangements include the reduction of background signals, for example ripples, caused by defect-free holes. In addition, multi-sensor designs can also enhance the signals received from defects by positioning pairs of sensors above the sides of the holes.

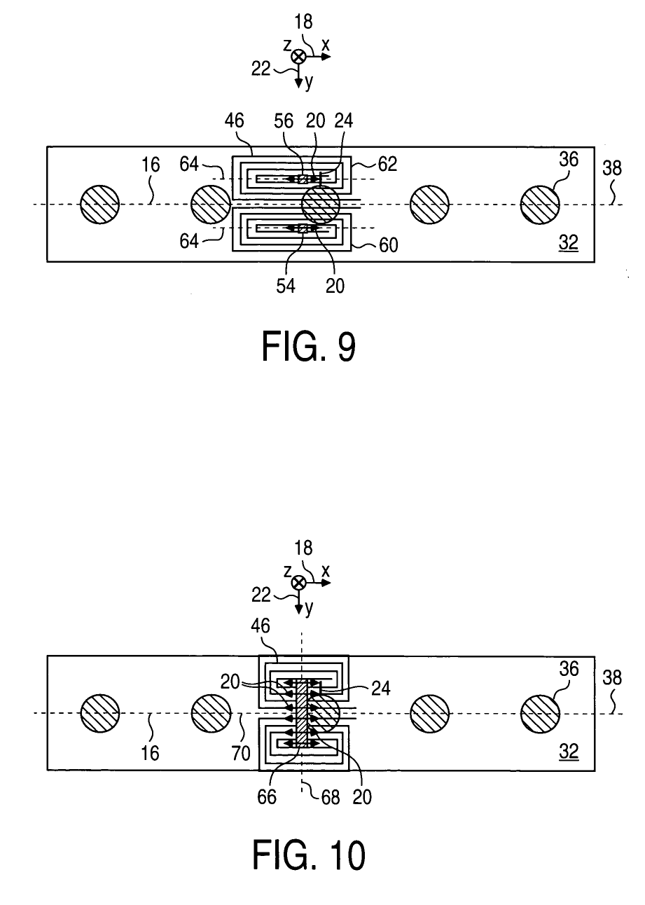

Eddy current probe arrangements containing two GMR sensors are illustrated in FIGS. 8 and 9. The arrangements are based on gradiometers. FIG. 8 illustrates an eddy current probe arrangement containing an elongated rectangular excitation coil 52, a first GMR sensor 54 and a second GMR sensor 56. Both the first and second GMR sensors are disposed within the elongated excitation coil 52 on the longitudinal axis 44 of the coil and are spaced from each other at a distance 58 equal to the distance between the centers of two adjacent holes 36. The axis of sensitivity 20 of both coils is perpendicular to the direction longitudinal axis 44. Scanning the specimen 32 by passing the longitudinal axis 44 along the axis of the row of holes 38, the first and second GMR sensors will simultaneously record signals from two adjacent holes. If the adjacent holes are both free of defects or cracks, the first and second sensors will record substantially equivalent signals. There may, however, be a small difference between the outputs of the first and second sensors. By taking the difference between the outputs of the two sensors, the background signal can be reduced.

FIG. 9 illustrates an embodiment of an eddy current probe containing a double spiral excitation coil 46, a first GMR sensor 54 and a second GMR sensor 56. The first GMR sensor 54 is disposed in the first spiral coil 60 and arranged so that the axis of sensitivity 20 is oriented along the direction of longitudinal axis 64 of the coil wires in the first spiral coil 60. Similarly, the second GMR sensor 56 is disposed in the second spiral coil 62 and arranged so that the axis of sensitivity 20 is oriented along the direction of longitudinal axis 64 of the coil wires in the second spiral coil 62.

As the eddy current probe of this embodiment is passed along the axis of the row of holes 38, the first and second sensors pass above the areas within the specimen 32 where defects and cracks 24 can initiate. This physical proximity between sensors and cracks provides the advantage of enhanced signal strength. When the eddy current probe of this embodiment is scanned above a hole 36 that is free of defects or cracks, the first and second sensors each record a double-peak signal of the same magnitude from the two hole edges. However, connecting the first and second sensors in an adder configuration cancels these double-peak signals from the two halves of the two hole edges. Therefore, only signals resulting from transverse cracks 24 will be registered. In addition, this signal from the transverse cracks 24 is enhanced due to the physical proximity between the crack 24 and the first or second sensor.

Another embodiment according to the present invention utilizes a linear array of GMR sensors. Although rapid and accurate detection of transverse cracks in a row of fastener holes is possible using single sensor probes, additional information regarding the size and location of defects and cracks can be obtained by mapping an entire region containing the holes. Scanning a single sensor-based eddy current probe over the region of interest can map the entire region containing the holes. However, the use of a single sensor-based probe would take a considerable amount of time and a significant number a scanning passes. The inspection time can be significantly reduced using a linear array of sensors to cover the desired region in a single scan.

A suitable arrangement for an array-based eddy current probe is illustrated in FIG. 10. A GMR sensor array 66 containing a plurality of individual GMR sensors is disposed within the area of a double spiral excitation coil 46 along a line 68 that is perpendicular to the axis of the row of holes 38. Each axis of sensitivity 20 for the GMR sensors is arranged parallel to the axis of the row of holes 38. Similar to the previously described two GMR sensor embodiment, pairs of sensors within the GMR sensor array 66 can be connected in an adder-type configuration to compensate for the signal resulting from the edge of each hole 36. Preferably, connected sensor pairs are selected for symmetrical arrangement about the axis of symmetry of the coil 70, which corresponds to the axis of the row of holes 38.

The number of sensors in the array 66 is chosen depending upon the size of the region to be scanned. In one arrangement of this embodiment, the total number of sensors in the array 66 is from about 16 up to about 32. Generally, the dimensions of holes 36 dictate the size of the region to be scanned. This allows the use of the masks of commercially available GMR sensors. Suitable sensors have a width of about 300 micrometers. The array 66 can contain GMR sensors bonded on the surface of a PCB. The terminals of the sensors can be connected on a custom-designed PCB. A reasonably good spatial resolution for this application can be obtained by using an array of sensors spaced at 0.5 mm pitch.

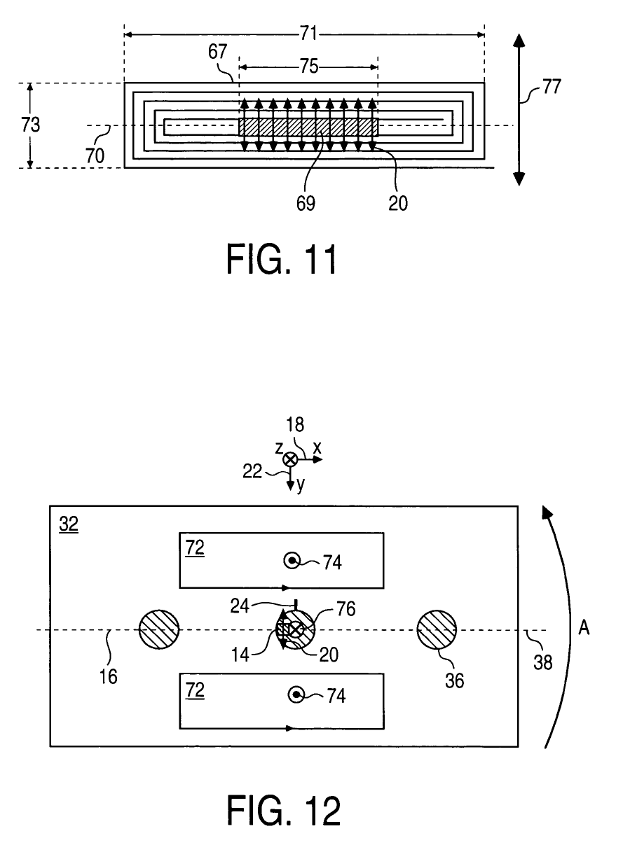

Another configuration of an eddy current probe utilizing an array of GMR sensors is illustrated in FIG. 11. This embodiment includes a single excitation coil 67 and a linear array of magnetic sensors 69. The single excitation coil 67 is a rectangular flat coil having a length 71 that is larger than its width 73. In addition, the length of the coil 71 is larger than the length 75 of the sensor array. For high-resolution detection arrangement of this embodiment, the total width 73 of the linear coil 67 is less than about 1 mm. For subsurface defects detection, a coil 67 having a larger width 73 is used to achieve higher penetration of the excitation field into the object being scanned.

Different configurations of the rectangular coil 67 are suitable for use in this embodiment. In one configuration, a flat spiral coil is printed on a rigid printed circuit board or a flexible substrate. The substrate may be an electrically-insulated substrate on which the set of excitation coils is deposited on using a photolithographic process or other planar technique. Alternatively, the excitation coils may be patterned from a metallic sheet without the use of an insulating substrate. In another configuration a flat spiral coil is manufactured of ribbon cable or parallel wires connected to form a spiral coil. In addition, the rectangular coil can be formed by winding a wire around the array of sensors 69.

The single flat rectangular excitation coil 67 enables manufacturing of coils of good reproducibility and precise geometry, and a precise alignment of the coil with respect to the sensor array 69 and the surface of the specimen under test. For example, when scanning a pipe for defects, a flexible coil manufactured on a flexible substrate that conforms of the curve surface of the pipe can be used.

Suitable magnetic sensors for use in the linear array of magnetic sensors 69 include GMR, SDT and AMR sensors. Hall effect sensors can also be used. Preferably, the magnetic sensors have small dimensions and high sensitivity to magnetic fields applied along their axes of sensitivity 20. The sensitive area of each magnetic sensor is about 50 microns by about 50 microns. A linear array of GMR sensors 69, with adjacent sensors spaced at 100 micrometers apart can be implemented on a silicon chip.

The axis of sensitivity 20 for each sensor in the array of GMR sensors 69 points in the same direction. This direction is perpendicular to the long direction. In addition, the axis of symmetry of the row of sensors corresponds to the axis of symmetry 70 of the excitation coil. As a result of this symmetry, the coil creates a zero magnetic field at the location of the sensor array 69 in the direction of the axis of sensitivity 20. Therefore, the output of all sensors of the array is zero when scanned over a defect-free specimen.

The GMR sensor array 69 is located on the top of the coil 67 such that during testing, the flat coil 67 is disposed between the sensor array 69 and the specimen under test. The scanning direction 77 is perpendicular to the long dimension 71 of the coil 67 and the axis of symmetry of the coil 70.

The types of defects that can be detected using this embodiment include small pits or corrosion at the surface of a specimen or buried under the specimen surface, defects in metallic structures under insulating coatings or painting and cracks that are oriented along the axis of sensitivity 20 of the sensors in the GMR sensor array 69. In addition, this embodiment can be used to map metallic patterns at the surface or buried under the surface of a component.

This embodiment provides advantages over the use of an array of separate eddy current probes to detect defects. For example, the signal conditioning for an eddy current probe containing an array of sensors is simplified as compared to the signal conditioning of an array of eddy current probes. The outputs of the array of sensors, for example 8, 16 or 32 sensors, can be monitored either in parallel, sequentially or both using multiplexing techniques. Multiplexing is used to reduce the number of the array terminals. If the outputs are monitored in parallel, each sensor's output is amplified by using instrumentation amplifiers.

The amplified signal of each sensor can be connected to the input channels of data acquisition boards or cards that convert the signals to digital format. The digital data can be processed in a computer, using standard signal processing software. The 3-D maps of the processed signals as a function of the spatial x-y coordinates can be displayed in real time on the computer monitor or other display devices. Alternatively, the processing of the sensors signals can be performed using standard lock-in amplifiers.

In addition, a higher spatial resolution of the measurement can be achieved using this embodiment. An array of sensors is more compact than an array of probes. Spacing of less than 1 mm between adjacent eddy current probes is difficult to obtain since the diameter of the excitation coil contained within each probe limits the spacing between adjacent probes. By using an array of GMR sensors disposed within a single coil, spacing between adjacent sensors can be achieved in the range of 100 micrometers. This spatial resolution is adequate for high-resolution inspection such as the inspection of corrosion and crack mapping. For deep crack detection, GMR sensor arrays are the only suitable configuration since deep crack detection generally requires excitation coils covering a larger area. Using an array of probes containing large diameter excitation coils is not practical, because the spatial resolution of the measurement is very poor.

The use of a single excitation coil also provides for less complex control circuitry. Circuitry for driving each excitation coil in a probe array is much more complex. Demultiplexing techniques must be implemented to provide excitation current to individual probes of the arrays. Because of this, the speed of the measurement is reduced for the array of probes.

This embodiment also facilitates better alignment among the various elements within an eddy current probe. An array of GMR sensors can be integrated on a single structure, for example a single printed circuit board or chip. The parallel alignment of the sensors is obtained during manufacture of the sensors array. Integration of identical eddy current probes on a single structure is more difficult.

In another embodiment according to the present invention, defects are detected using the returning magnetic flux exterior to the excitation coil. Typically, eddy current probes utilize the direct magnetic flux created inside the excitation coil to create eddy currents. The perturbation of these eddy currents due to a defect is measured using a magnetic field sensor usually located inside the area of the excitation coil. By contrast, eddy current probes and methods for using the eddy current probes according this embodiment utilize the returning magnet flux created by the excitation coil and exterior to the coil to create eddy currents remote from the coil area on the backside of a specimen. In general, this returning field, since it is spread over a large area around the coil, is much weaker than the internal main field. When the specimen contains fastener holes, these holes provide a path for the returning magnetic flux. Therefore the holes act as magnetic flux concentrators for the returning flux. Consequently, circular eddy currents of significant intensity can be induced on the backside of the plate, around the fastener holes. By placing sensors above the holes remotely from the excitation coil, the backside cracks around holes can be reliably detected.

This embodiment is illustrated in FIG. 12. Two flat rectangular excitation coils 72, constructed from, for example, ribbon cable, are disposed adjacent to the top-side of the specimen and arranged symmetrically about the axis of the row of holes 38. The current in both excitation coils flows in the direction of arrow A, and the magnetic flux internal to both coils 74 is directed perpendicular to the plane in which the two coils 72 are disposed. These fluxes travel up through the specimen 32, being attenuated by the eddy current field created in the specimen within the area defined by the coils 72.

If the frequency is low enough such that the excitation magnetic field is not totally canceled by the eddy current field, a magnetic flux will exit on the backside of the specimen 32. Since the magnetic field lines of the coils are closed loops, this exiting magnetic field returns to the surface of the specimen 32 and is focused by the central hole in FIG. 12. Because the area of the hole 36 is small compared to the length or area of the excitation coils 72, the holes act as concentrators for the returning flux. The returning flux 76 passing through the holes 36 in a direction opposite to the excitation flux creates significant eddy currents around the hole 36 on the backside of the specimen 32.

A GMR sensor 14, disposed adjacent the specimen 32 between the excitation coils 72 and arranged so that its axis of sensitivity 20 runs perpendicular to the axis of the row of holes 38, detects the returning flux 76. Since the eddy currents around the hole 36 are attenuated toward the surfaces of the specimen 32, this embodiment is preferable for detecting deeply buried flaw, on or near the backside of the specimen 32. In general, the excitation coils 72 are placed far enough from the holes 36 so that no eddy currents are created around the holes 36 at the top-surface of the specimen 32. Therefore, eddy current probes according to this embodiment are not preferable for detecting surface or near surface cracks around holes.

Because the excitation coils 72 are located outside the area of fastener holes, this embodiment of the eddy current probe is suitable for use in applications where the fasteners disposed in the holes 36 have heads that protrude from the surface of the specimen 32. The use of traditional arrangements of reflection probes with these types of fasteners would require a high lift-off of the excitation coils from the surface of the specimen, reducing the capability of detection of deeply buried cracks. This embodiment, however, permits the coils to be scanned much closer to the specimen surface, enhancing probe sensitivity.

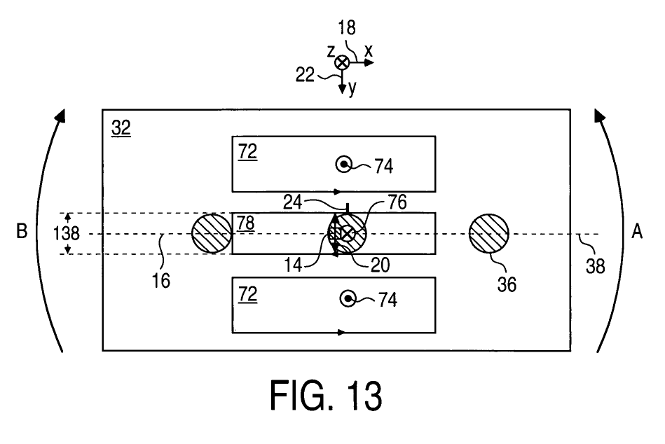

In order to provide for the detection of both deeply buried defects and surface defects, a three-excitation coil embodiment of the eddy current probe can be used. This embodiment is illustrated in FIG. 13 and is similar to the two coil embodiment illustrated in FIG. 12 with a third flat rectangular excitation coil 78 disposed adjacent the specimen 32 between the first two coils 72. The current in the third excitation coil 78 is made to flow in the direction of arrow B, the opposite direction from the current flow in the other two flat rectangular excitation coils 72. This embodiment enhances or magnifies the magnet flux passing through the hole 36, because the returning flux 76 from the two coils 72 is combined with the main flux produced by the third coil 78. In addition to enhancing the returning flux 76, the eddy currents created at the surface of the specimen 32 by the third coil 78 facilitate the detection of surface and near surface cracks.

### EXAMPLES

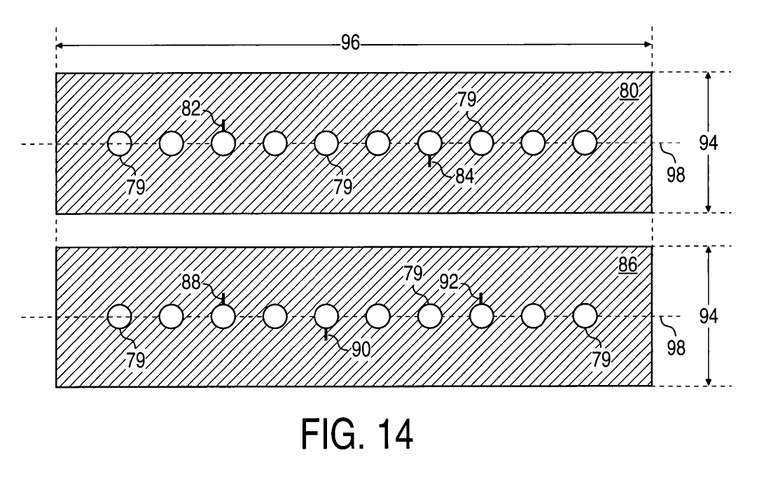

Studies were conducted using embodiments of the present invention to detect buried cracks in test specimens. The test specimens were configured to simulate transverse defects or cracks, as these are the most frequently encountered defects. As is illustrated in FIG. 14, two specimen metal plates were used. Both specimen metal plates were constructed from stacks of aluminum plates where each aluminum plate has a thickness of about 3.2 mm (0.125 in.). Overall, each specimen metal plate has a width 94 of about 50 mm (2 in.) and a length 96 of about 280 mm (11 in.).

Both plates contained a plurality of fastener holes 79 arranged in rows. Ten holes 79, each having a diameter of about 6.3 mm (0.25 in.) were drilled in each plate in rows aligned with the longitudinal symmetry axis 98 of each plate. The distance between the centers of adjacent holes was 19 mm (0.75 in.).

Various holes were provided with transverse cracks emanating from their edges. The length of these cracks ranged from about 1 mm (0.04 in.) up to about 2.5 mm (0.1 in.). The first plate 80 contained relatively long cracks transverse cracks, for example a first transverse crack 82 that was 2.5 mm long and a second transverse crack 84 that was 2 mm. The second plate 86 contained relatively shorter cracks, for example a third transverse crack 88 that was 2 mm long, a fourth transverse crack 90 that was 1 mm long and a fifth transverse crack 92 that was 1.5 mm long. All of the cracks extended into the holes by about 1 mm. This amount of extension is less than one third of the thickness of the plate, emulating corner cracks.

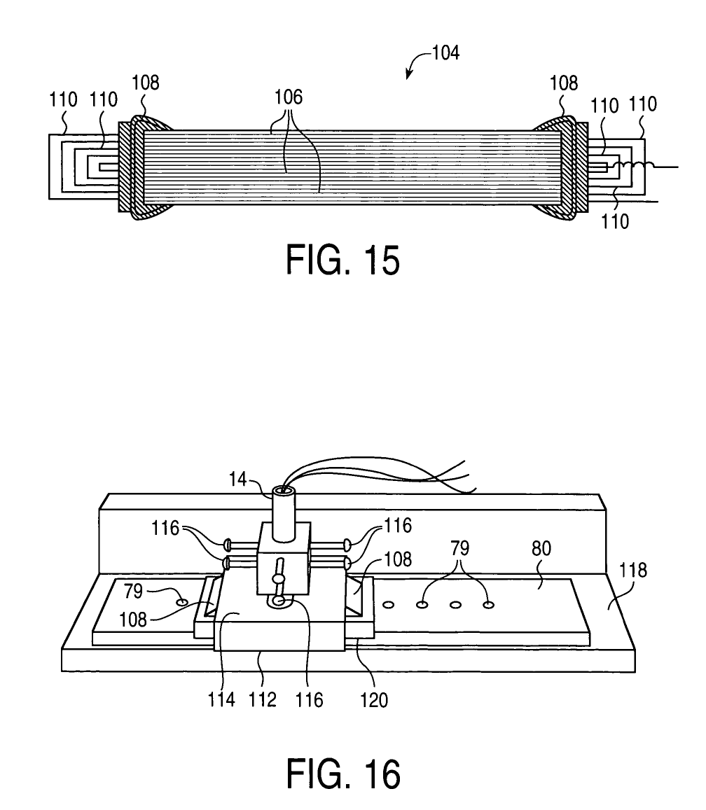

An eddy current probe in accordance with the embodiment illustrated in FIG. 5 was used. This eddy current probe included a flat rectangular excitation coil 42 constructed using a ribbon cable 104 containing twenty six parallel wires 106, as illustrated in FIG. 15. The ribbon cable included two standard ribbon cable connectors 108 attached to either end of the coil 42. The excitation coil 42 was formed by connecting the appropriate pairs of wires in the ribbon cable 104 using short jumper wires 110 attached to the portion of the connector 108 associated with those wires. Overall, the width 100 of the coil was 12.6 mm. This width 100, which is equal to twice the diameter of each hole 36, was selected to obtain the maximum eddy current density along a line tangential to the holes 36 and parallel to the axis of the row of holes 38. The length of the coil 42 was about 60 mm.

As is shown in FIG. 16, the flat rectangular excitation coil 42 was mounted on the bottom surface 112 of a squared shape block of plastic 114. Suitable plastics include Delrin®, commercially available from E.I. du Pont de Nemours and Company of Wilmington, Del. The GMR sensor 14 was positioned above the ribbon cable 104. Four pairs of screws 116 permit adjustment of the GMR sensor 14 with respect to the ribbon cable 104. The specimen 80 to be scanned was placed in a guide 118 constructed from two blocks of wood that were longer than the specimen 80. The block of plastic 114 is passed over the specimen 80 such that the bottom surface 120 is on contact with the specimen 80.

The specimen 80 was oriented to simulate cracks or defects that were buried at a depth of 3.2 mm depth, and the excitation coil 42 and GMR sensor 14 were aligned to minimize the signal ripples produced by defect free holes. An AC power source provided an alternating current of 2.5 A amplitude to the excitation coil 42. During the scanning of the probe along the row of holes, the GMR sensor output signal was amplified by using a Standard Research Systems SR560 low noise preamplifier. The amplitude and phase of the amplified signal were extracted by using a Standard Research Systems SR850 lock-in amplifier. To further enhance the defect detection capability, the signal produced by defects was “filtered” from background signals, for example signals resulting from a hole's edge or from misalignments between the coil and sensor, by monitoring the out-of-phase component (Y signal) of a lock-in amplifier (not shown) in communication with the GMR sensor 14. The phase of the reference signal generated by the lock-in amplifier was adjusted until background signals were minimized. For optimum detection of the defects buried at 3.2 mm below the surface, the excitation frequency was 2 kHz.

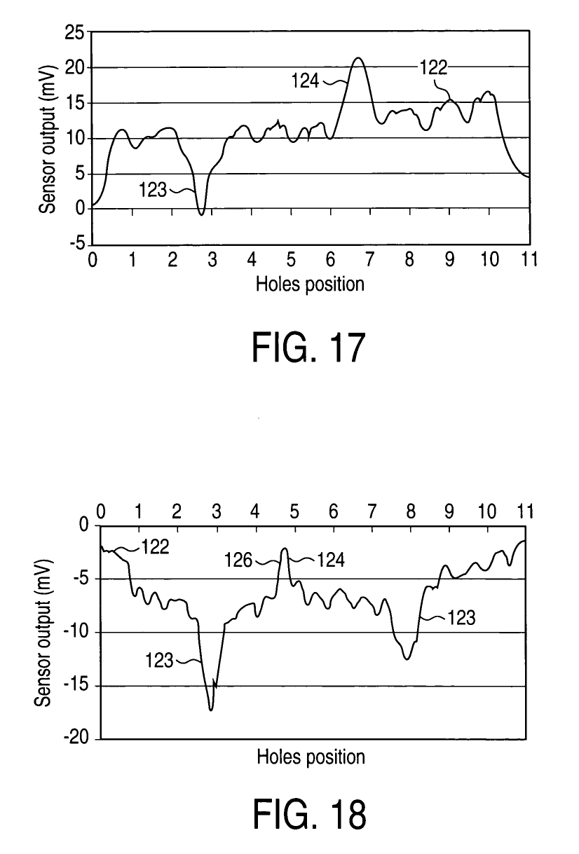

The out-of-phase output of the lock-in amplifier for the first plate 80 is shown in FIG. 17. The out-of-phase output of the lock-in amplifier for the second plate 86 is shown in FIG. 18. The negative peaks 123 indicate cracks extending transverse to the direction of the scan to the left of the GMR sensor 14, for example the first transverse crack 82 in FIG. 14. The positive peaks 124 indicate cracks extending transverse to the direction of the scan to the right of the GMR sensor, for example the second transverse crack 84 in FIG. 14.

As is shown in FIG. 18, the shortest crack, that is the fourth transverse crack 90, has a length of about of 1 mm and produces a clearly distinguishable positive peak 126. The amplitude of the signal from this defect is approximately 4 times larger than the background signal coming from defect free holes. Since the scanning was manual and the scanning speed was not constant, the positions of peaks and the ripples corresponding to the defect-free holes do not correspond precisely to the positions of holes indicated in these figures.

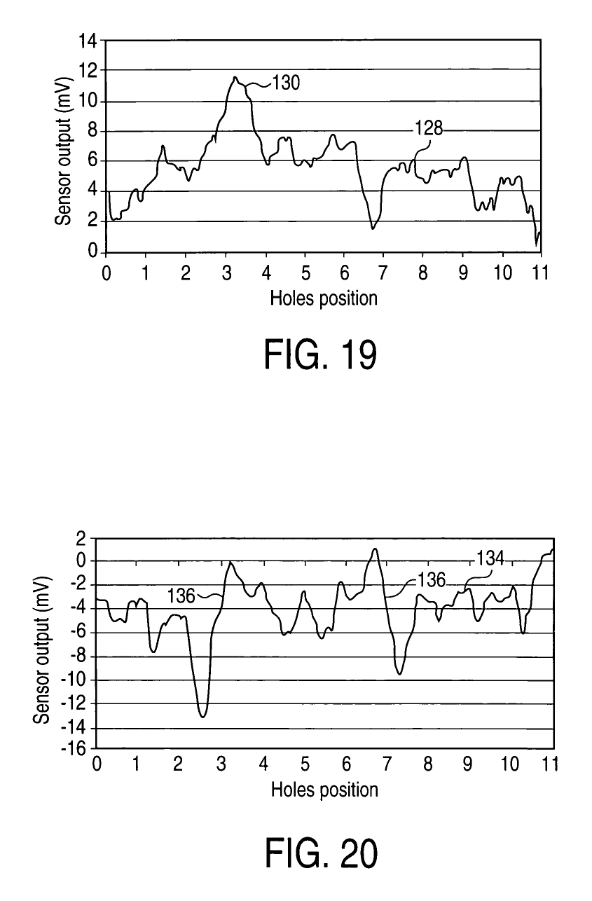

In an alternative example, a defect-free plate was placed over top of the first plate 80 and another scan was performed, simulating cracks located at a depth of about 4.2 mm below the surface. The optimum detection of the cracks was obtained at an excitation frequency of 1 kHz, and at a reference phase of 32 deg. The output signal 128 is shown in FIG. 19. The amplitude of the peak 130 corresponding to the 2.5 mm first transverse crack is about three times larger than the signal from a defect free hole.

Tests were also conducted using a configuration of the eddy current probe containing a flat double spiral coil 46 as illustrated in FIG. 6. Again, the double spiral coil 46 was manufactured from a ribbon cable and was configured such that the current in the central region flows in the same direction. The coil has a total of 40 turns and an overall width 132 of 54 mm. To obtain a self-nulling probe, the axis of sensitivity 20 of the GMR sensor 14 was oriented along the direction of the coil wires.

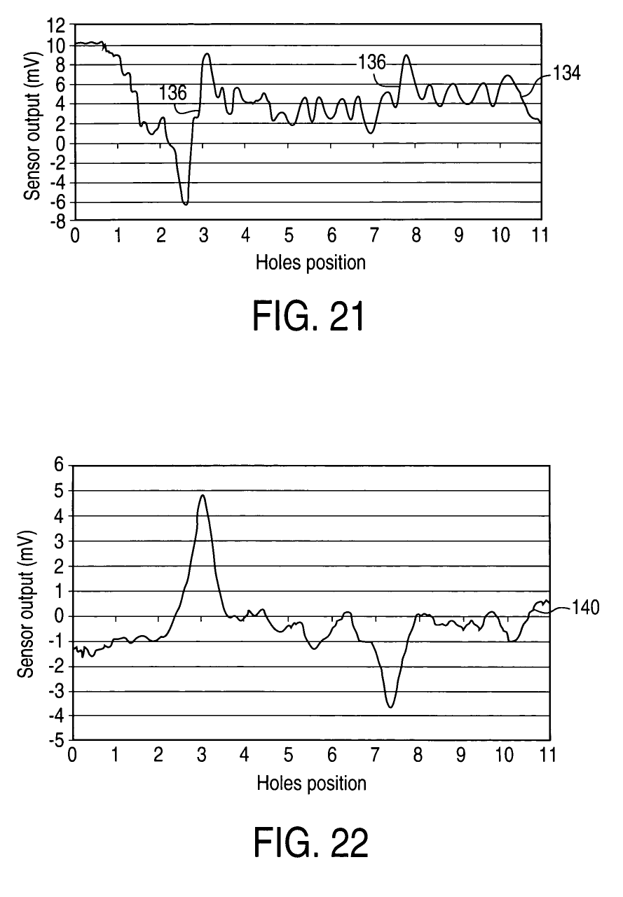

As in the first experiment, the new probe was scanned along the axis of the two specimens to detect the cracks buried 3.2 mm below the surface. The out-of-phase signals 134 obtained at 1 kHz excitation frequency are shown in FIGS. 20 and 21 for the first and second plates respectively. This eddy current probe configuration indicates a crack as a two-peak signal 136, one positive peak and one negative peak. A left-side crack results in a signal having positive slope between the two peaks, and a right-side crack results in a signal having negative slope between the two peaks. The results indicate that notches longer than 1.5 mm can be easily detected using this probe, while the 1 mm notch gives a signal comparable to the background signal from defect free holes.

Comparing the results from the two eddy current probe configurations, larger background signals, the ripples from the defect free holes, were observed for double spiral configuration. The double spiral configuration also yielded a more pronounced interference between adjacent holes signals and influence of the end edges of specimens. A configuration using a shorter double spiral coil could reduce this interference.

Additional tests were run using embodiments of the eddy current probe as illustrated in FIGS. 12 and 13. Again, the flat rectangular excitation coils used in these configurations were constructed from ribbon cable using jumper cables to connect the appropriate ends of the ribbon wires. The third rectangular excitation coil 78 shown in FIG. 13 has 10 turns and a mean diameter of 6 mm by connecting 20 wires over a width 138 of 12 mm. The first two rectangular excitation coils 72 were disposed symmetric about and adjacent to the third coil 78. Each one of the first two coils 72 contained 8 turns and a mean diameter of 11 mm. By selectively connecting the ends of single ribbon cable, this single ribbon cable was used for both the two-coils configuration of FIG. 12 and the three-coils configuration of FIG. 13. In addition, using only the third rectangular excitation coil simulates the probe configuration of FIG. 5. This flexible design enables a direct comparison of the performances of the various excitation coil configurations.

The two-coil probe embodiment shown in FIG. 12 was scanned along the first plate 80, with the cracks on the backside of the plate 3.2 mm under the surface. The excitation frequency was 2 kHz. The out-of-phase component 140 of the GMR sensor's 14 output is shown in FIG. 22. The results are comparable to those obtained using a single rectangular excitation coil 42 in terms of crack signal to background signal ratio. The three-coil configuration of FIG. 13 produced a slightly improved crack signal to background signal ratio.

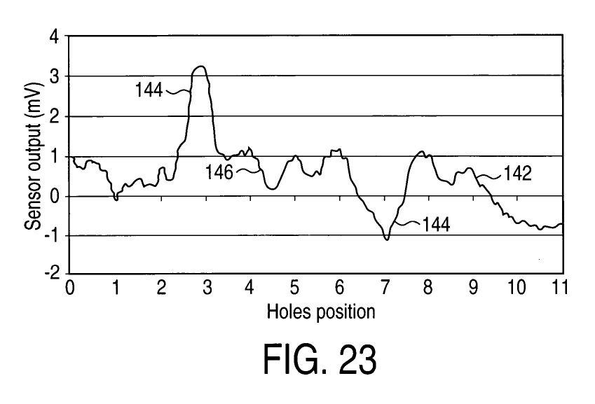

In another test, a metal plate having a thickness of about 1.6 mm was placed on the top of the first plate 80 to test the capability of these configurations to detect defects buried at 4.8 mm below the surface. The out-of-phase signal component 142 generated by the three-coil probe configuration at a frequency of 1 kHz is shown in FIG. 23. The crack signal 144 is about three times larger than the background signal 146 caused by the defect-free holes. The central coil probe and two-coil probe configurations showed a poorer capability of detection of cracks at this depth. The ratio of crack signal to background signal was less than two to one for these configurations.

Other embodiments and uses of the present invention will be apparent to those skilled in the art from consideration of this application and practice of the invention disclosed herein. The present description and examples should be considered exemplary only, with the true scope and spirit of the invention being indicated by the following claims. As will be understood by those of ordinary skill in the art, variations and modifications of each of the disclosed embodiments, including combinations thereof, can be made within the scope of this invention as defined by the following claims.

1. An eddy current probe for detecting defects in an electrically conductive specimen under test (SUT), the eddy current probe comprising:
a. at least one excitation coil having a cross-section disposed within a common plane, the at least one excitation coil having a symmetry axis within the common plane, wherein the at least one excitation coil creates a magnetic field and eddy currents into SUT; and
b. at least one magnetic senor operable to be positioned on the symmetry axis of the at least one excitation coil and having a sensitive axis operable to be disposed within the common plane perpendicular to the symmetry axis of the at least one excitation coil.

2. The eddy current probe according to claim 1, wherein the at least one excitation coil comprises a substantially rectangular cross-section.

3. The eddy current probe according to claim 1, wherein the at least one excitation coil comprises a pair of substantially identical excitation coils symmetrically disposed about the symmetry axis.

4. The eddy current probe according to claim 3, wherein each excitation coil of the pair of substantially identical excitation coils comprises a substantially rectangular cross-section.

5. The eddy current probe according to claim 3, wherein the pair of substantially identical excitation coils are operable to be interconnected such that when an electric current is passed through the pair of substantially identical excitation coils, each excitation coil of the pair of substantially identical excitation coils create a magnetic field in the same direction.

6. The eddy current probe according to claim 3, further comprising a third excitation coil configured to be located between the pair of substantially identical excitation coils, wherein the three excitation coils are operable to be interconnected such that when an electric current is passed through the three excitation coils, the magnetic field created by the third excitation coil and the magnetic field created by the pair of substantially identical excitation coils are in opposite directions.

7. The eddy current probe according to claim 6, wherein each of the three excitation coils comprises a substantially rectangular cross-section.

8. The eddy current probe according to claim 3, wherein the pair of substantially identical excitation coils is operable to be configured such that they intersect.

9. The eddy current probe according to claim 1, wherein the at least one excitation coil comprises a flat coil having at least one layer.

10. The eddy current probe according to claim 9, wherein the flat coil comprises multiple layers.

11. The eddy current probe according to claim 1, wherein the at least one excitation coil comprises:
a. a ribbon cable comprising a plurality of parallel insulated wires and having two ends;
b. a pair of electrical connectors, each electrical connector attached to the ribbon cable; and
c. a plurality of jumper wires operable to be attached to the electrical connectors to form the at least one excitation coil.

12. The eddy current probe according to claim 1, wherein the at least one excitation coil is patterned on an electrically insulated substrate.

13. The eddy current probe according to claim 1, wherein the at least one excitation coil is patterned from a metallic sheet.

14. The eddy current probe according to claim 1, wherein the at least one excitation coil comprises an electrically conductive foil.

15. The eddy current probe according to claim 1, wherein the set of excitation coils is patterned from a metallic sheet without an insulating substrate.

16. The eddy current probe according to claim 1, wherein the at least one magnetic sensor comprises a plurality of substantially identical magnetic sensors.

17. The eddy current probe according to claim 16, wherein the plurality of substantially identical magnetic sensors are operable to be disposed in a linear array.

18. The eddy current probe according to claim 1, wherein the at least one magnetic sensor comprises at least one magnetoresistive sensor.

19. The eddy current probe according to claim 18, wherein the magnetoresistive sensor comprises at least one giant magnetoresistive sensor, anisotropic magnetoresistive sensor, or spin-dependent tunneling sensor.

20. The eddy current probe according to claim 1, wherein the at least one magnetic sensor comprises at least one Hall-effect sensor

21. An eddy current testing system for detecting and monitoring defects in an electrically conductive specimen under test (SUT), the eddy current testing system comprising:
a. an eddy current probe according to claim 1;
b. an AC power supply electrically connected to the at least one excitation coil of the eddy current probe;
c. an amplifier electrically connected to the at least one magnetic sensor of the eddy current probe;
d. an amplitude and phase detector capable of receiving the signal from the amplifier.

22. The eddy current system according to claim 21, further comprising a data recorder in communication with the detector.

23. The eddy current system according to claim 21, further comprising a display in communication with the detector.

24. The eddy current system according to claim 21, wherein the amplitude and phase detector comprises a lock-in amplifier.

25. The eddy current system according to claim 21, wherein the amplitude and phase detector comprises program code stored on a computer readable media.

26. The eddy current system according to claim 21, wherein the eddy current probe comprises a plurality of magnetic sensors and wherein the eddy current testing system is operable to compute the sum of or difference between a plurality of output signals from the plurality of magnetic sensors.

27. An eddy current probe for detecting defects within a specimen under test (SUT) comprising:
a. a flat excitation coil of rectangular cross-section having an axis of symmetry within a plane of the cross-section; and
b. a linear array of magnetoresistive sensors disposed at the axis of symmetry of the flat excitation coil, each magnetoresistive sensor in the array having a sensitive axis operable to be disposed perpendicular to the axis of symmetry of the excitation coil.

28. A method for detecting defects within a specimen under test (SUT) comprising scanning an eddy current probe according to claim 1 above the top surface of the SUT, wherein the cross-section of the at least one excitation coil of the eddy current probe is coplanar with the top surface of the SUT.

29. A method for detecting cracks in a specimen under test (SUT) having at least one row of fastener holes, wherein each row of fastener holes has a symmetry axis that intersects the centers of all holes in the row, comprising scanning the eddy current probe according to claim 1 above the top surface of the SUT along the symmetry axis of the fastener holes such that the at least one magnetic sensor passes along the symmetry axis of the row of fastener holes.

30. An eddy current probe comprising:
a. a flat excitation coil having a substantially rectangular cross-section and having an axis of symmetry within the plane of the cross-section;
b. two magnetoresistive sensors operable to be disposed at the axis of symmetry of the excitation coil, each magnetoresistive sensor having a sensitive axis operable to be disposed perpendicular to the axis of symmetry of the excitation coil, wherein the two magnetoresistive sensors are operable to be connected in a gradiometer configuration.

31. A method for detecting cracks in a specimen under test (SUT) having at least one row of fastener holes, wherein each row of fastener holes has a symmetry axis that intersects the centers of all holes in the row, comprising:
a. configuring the eddy current probe according to claim 30 such that the distance between the two sensors is substantially the same as the distance between the centers of two adjacent fastener holes; and
b. scanning the eddy current probe according to claim 30 above the top surface of the SUT such that the two magnetoresistive sensors pass along the symmetry axis of the row of fastener holes.

32. An eddy current probe for detecting defects in an electrically conductive specimen under test (SUT), the eddy current probe comprising:
a. a pair of substantially identical excitation coils having substantially rectangular cross-sections operable to be disposed within a common plane, the pair of excitation coils having a first symmetry axis and a second symmetry axis orthogonal to the first symmetry axis within the common plane, wherein the pair of excitation coils are interconnected such that they create magnetic field and eddy currents into SUT in opposite directions if an electric current is passed through the pair of excitation coils; and
b. at least one magnetic sensor operable to be positioned on the second symmetry axis of the pair of excitation coils and having a sensitive axis operable to be disposed within the common plane perpendicular to the second symmetry axis of the pair of excitation coils.

33. The eddy current according to claim 32, wherein the pair of excitation coils intersect.

34. The eddy current probe according to claim 32, wherein the pair of excitation coils comprises a flat coil having at least one layer.

35. The eddy current probe according to claim 32, wherein the pair of excitation coils comprises a flat coil having multiple layers.

36. The eddy current probe according to claim 32, wherein the pair of excitation coils comprises:
a. a ribbon cable comprising a plurality of parallel insulated wires and having two ends;
b. a pair of electrical connectors, each electrical connector attached to the ribbon cable; and
c. a plurality of jumper wires operable to be attached to the electrical connectors to form the at least one excitation coil.

37. The eddy current probe according to claim 32, wherein the at least one magnetic sensor comprises a plurality of substantially identical magnetic sensors.

38. The eddy current probe according to claim 32, wherein the plurality of substantially identical magnetic sensors are operable to be disposed in a linear array.

39. The eddy current probe according to claim 32, wherein the at least one magnetic sensor comprises at least one pair of substantially identical magnetic sensors symmetrically disposed about the first symmetry axis.

40. The eddy current probe according to claim 32, wherein the at least one magnetic sensor comprises at least one magnetoresistive sensor.

41. The eddy current probe according to claim 32, wherein the at least one magnetic sensor comprises at least one Hall-effect sensor.

42. An eddy current testing system for detecting and monitoring defects in an electrically conductive specimen under test (SUT), the eddy current testing system comprising:
a. an eddy current probe according to claim 32;
b. an AC power supply electrically connected to the pair of excitation coils of the eddy current probe;
c. an amplifier electrically connected to the at least one magnetic sensor of the eddy current probe; and
d. an amplitude and phase detector capable of receiving the signal from the amplifier.

43. The eddy current system according to claim 41, further comprising a data recorder in communication with the detector.

44. The eddy current system according to claim 41, fuirther comprising a display in communication with the detector.

45. The eddy current system according to claim 41, wherein the amplitude and phase detector comprises a lock-in amplifier.

46. The eddy current system according to claim 41, wherein the amplitude and phase detector comprises program code stored on a computer readable media.

47. The eddy current system according to claim 41, wherein the eddy current probe comprises a plurality of magnetic sensors and wherein the eddy current testing system is operable to compute the sum of or difference between a plurality of output signals from the plurality of magnetic sensors.

48. An eddy current probe for detecting defects within a specimen under test (SUT) comprising:
a. a pair of flat excitation coils having a rectangular cross-section and having a first symmetry axis and a second symmetry axis orthogonal to the first symmetry axis within the plane of the cross-section; and
b. a linear array of magnetoresistive sensors disposed at the second symmetry axis of the pair of excitation coils, each magnetoresistive sensor in the array having a sensitive axis disposed within the plane of the cross-section, wherein the sensitive axis is perpendicular to the second symmetry axis of the pair of excitation coils.

49. An eddy current probe for detecting cracks in a specimen under testing (SUT) having a row of fastener holes, wherein the row of fastener holes has a symmetry axis that intersects the centers of all holes in the row, wherein the eddy current probe comprises:
a. a pair of flat excitation coils having rectangular cross-sections and having a first symmetry axis and a second symmetry axis orthogonal to the first symmetry axis within the plane of the cross-section;
b. a magnetoresistive sensor disposed at the intersection of the first symmetry axis and the second symmetry axis of the pair of excitation coils, the magnetoresistive sensor having a sensitive axis disposed within the plane of the cross-section, wherein the sensitive axis of the magnetoresisitve sensor is perpendicular to the second symmetry axis of the excitation coil.

50. A method for detecting defects within a specimen under test (SUT) comprising scanning an eddy current probe according to claim 32 above the top surface of the SUT, wherein the cross-section of the pair of excitation coils of the eddy current probe is coplanar with the top surface of the SUT.

51. A method for detecting cracks in a specimIn under test (SUT) having at least one row of fastener holes, wherein each row of fastener holes has a symmetry axis that intersects the centers of all holes in the row, comprising scanning the eddy current probe according to claim 32 above the top surface of the SUT along the symmetry axis of the fastener holes such that the first symmetry axis of the excitation coils substantially coincides with the symmetry axis of the row of fastener holes.
